(19) United States
(12) Patent Application Publication
(10) Pub. No.: US 2009/0021710 A1
(43) Pub. Date: Jan. 22, 2009

(54) IMMERSION LITHOGRAPHY APPARATUS AND METHOD OF FORMING PATTERN USING THE SAME

(76) Inventor: Eun-Soo Jeong, Gangnam-gu (KR)

Correspondence Address: SHERR & VAUGHN, PLLC, 620 HERNDON PARKWAY, SUITE 200, HERNDON, VA, 20170, US

(21) Appl. No.: 12/169,589

(22) Filed: Jul. 8, 2008

(30) Foreign Application Priority Data
Jul. 20, 2007 (KR) 10-2007-0072644

(51) Int. Cl. G03B 27/42; G03F 7/20

(52) U.S. Cl. 355/53; 430/322

(57) ABSTRACT

An immersion lithography apparatus and/or a method of forming a pattern. In an immersion lithography apparatus, an intermediate medium may not directly contact the photoresist layer and it may be possible to maximize the transport speed of a wafer without generating defects (e.g. water marks). An intermediate medium may include a first intermediate medium and a second intermediate medium that for an interface. The interface may be controlled by charges through an electrode to control a numerical aperture. Accordingly, a pattern may be formed using an immersion lithography apparatus capable of controlling a numerical aperture so that a relatively high refractive index can be achieved.

The present application claims priority under 35 U.S.C. 119 to Korean Patent Application No. 10-2007-0072644 (filed on Jul. 20, 2007), which is hereby incorporated by reference in its entirety.

### BACKGROUND

Embodiments relate to immersion lithography. Embodiments relate to an immersion lithography apparatus capable of controlling numerical aperture and/or a method of forming a pattern using the immersion lithography apparatus.

In order to fabricate a semiconductor device with refined features, the size of patterns may be minimized. In order to obtain a relatively fine pattern, an exposure apparatus and resist may be used. An example exposure apparatus, a KrF light source having a wavelength of approximately 248 nm or an ArF light source having a wavelength of approximately 193 nm may be used in a production process. A light source wavelength may be relatively short and/or lens numerical aperture relatively large using a F2 light source (e.g. at 157 nm) or an EUV light source (e.g. at 13 nm).

However, when the light source wavelength is relatively short, since a new exposure apparatus may be required, there may be negative cost effects in a manufacturing process. When the numerical aperture is relatively large, although resolution is increased, the width of focus depth may be relatively small. Immersion lithography may be used to mitigate negative cost effects and focus depth limitations. Air (e.g. having a refractive index of 1.0) may be used as an intermediate medium between an exposure lens and a wafer on which a photoresist layer is formed in a non-immersion lithography process. In an immersion lithography process, a fluid (e.g. H2O or an organic solvent having a refractive index greater than 1.0) may be used as an intermediate medium. In an immersion lithography process, it may be possible to use light having a relatively short wavelength and/or a lens having a relatively high numerical aperture using a light source with a relatively large wavelength to effectively implement a lithography process. As a reference, H2O has a refractive index of 1.43 at a wavelength of 193 nm.

An immersion lithography process is an exposure process that may improve the focus depth compared with a non-immersion lithography process. When an immersion lithography process is used, a smaller fine pattern may be formed using the same or similar exposure wavelength as used in a non-immersion lithography process.

FIG. 1 is a sectional view illustrating an immersion lithography apparatus. Wafer 20 may be provided on and/or over wafer stage 10. Pattern forming photoresist layer 30 may be formed on and/or wafer 20. Intermediate medium 40 (e.g. H2O or an organic solvent) may be provided over photoresist layer 30. Reticle 50 may be provided on intermediate medium 40. In an immersion lithography apparatus, light 1 may pass through reticle 50 and intermediate medium 40 to be applied to photoresist layer 30 so that photoresist layer 30 may be patterned.

However, in immersion lithography apparatus, since an intermediate medium (e.g. such as H2O or organic solvent) may be in direct contact with a photoresist layer, defects (e.g. water marks) may occur. Due to an adhesive force between an intermediate medium having a relatively high refractive index and a reticle, it may be difficult to increase the transport speed of a wafer and/or maximize productivity.

### SUMMARY

Embodiments relate to an immersion lithography apparatus with maximized transport speed of a wafer and/or maximized productivity, without generating defects (e.g. water marks). In embodiments, an intermediate medium does not directly contact a photoresist layer.

In embodiments, a pattern is formed using an immersion lithography apparatus capable of controlling numerical aperture.

In embodiments, an immersion lithography apparatus may receive a wafer on and/or over a wafer stage. A pattern forming photoresist layer may be formed on and/or over the wafer. An intermediate medium receptor formed of a transparent material may be provided on and/or over the photoresist layer. The intermediate medium receptor may be capable of controlling a refractive index. A reticle may be provided on and/or over the intermediate medium receptor.

An intermediate medium receptor may include a case and an electrode, in accordance with embodiments. The case and/or the electrode may be formed of a transparent material. The case and the electrode may be closely adhered to each other so that an intermediate medium receiving space is formed. A first intermediate medium and a second intermediate medium having different specific gravities may be received in the intermediate medium receiving space, with an interface between the first intermediate medium and the second intermediate medium. In embodiments, the intermediate medium receptor may receive H2O as the first intermediate medium and an oil based medium as the second intermediate medium. In embodiments, the interface between the first intermediate medium and the second intermediate medium may be altered in the intermediate medium receptor by electrostatic force of charges applied to the electrode so that predetermined numerical aperture is obtained

In embodiments, a method of forming a pattern includes at least one of the following steps: Forming an underlayer and a photoresist layer on and/or over a semiconductor substrate. Providing an intermediate medium receptor (e.g. including transparent material) that is capable of controlling a refractive index on and/or over the photoresist layer by applying charges. Controlling the charges applied to the intermediate medium receptor to set a predetermined numerical aperture. Performing an immersion lithography process on and/or over the intermediate medium receptor to pattern the photoresist layer. Patterning the underlayer using the patterned photoresist layer.

In embodiments, the intermediate medium does not directly contact the photoresist layer. Accordingly, transport speed of a wafer without generating defects (e.g. water marks) may be maximized, which my maximize productivity. In embodiments, an interface may be changed between a plurality of media in an intermediate medium receptor by controlling elastic force, which may be used to control a numerical aperture. In embodiments, a pattern may be formed using an immersion lithography apparatus capable of controlling the numerical aperture so that a relatively high refractive index may be achieved.

### DRAWINGS

FIG. 1 is a sectional view illustrating a immersion lithography apparatus.

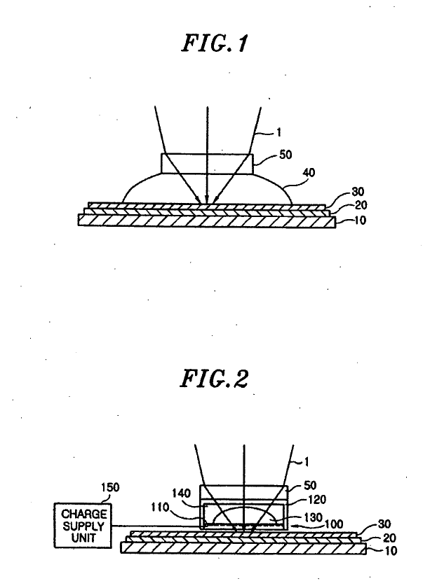

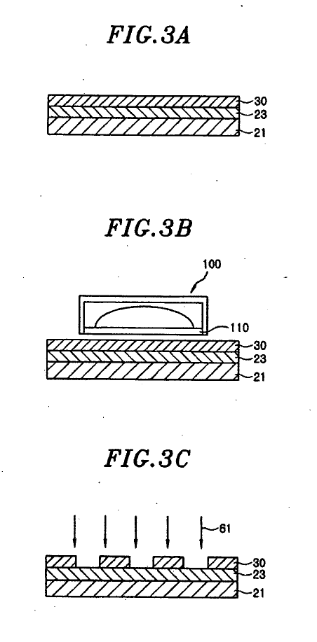

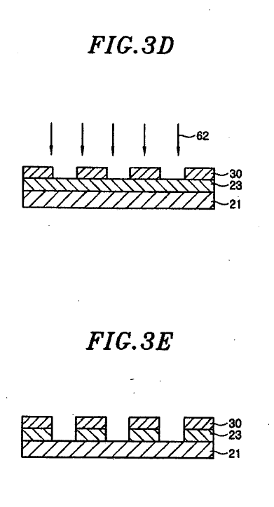

Example FIG. 2 is a sectional view illustrating an immersion lithography apparatus, in accordance with embodiments.

Example FIGS. 3A to 3E are sectional views of a semiconductor device illustrating a process of forming a pattern using an immersion lithography apparatus, in accordance with embodiments.

### DESCRIPTION

Example FIG. 2 is a sectional view illustrating an immersion lithography apparatus, according to embodiments. Wafer 20 is received on and/or over wafer stage 10. Pattern forming photoresist layer 30 may be formed on and/or over wafer 20. Intermediate medium receptor 100, capable of controlling refractive index, may be provided on and/or over photoresist layer 30. Reticle 50 may be provided on and/or over intermediate medium receptor 100.

Intermediate medium receptor 100 may include case 120 and electrode 110. Case 120 and/or electrode 110 may be formed of or include transparent material. Case 120 and electrode 110 may be adhered to each other to form an intermediate medium receiving space. An intermediate medium receiving space may hold a first intermediate medium 130 (e.g. having a relatively low specific gravity) and a second intermediate medium 140 (e.g. having a relatively high specific gravity). There may be an interface (e.g. a natural interface) between the first intermediate medium 130 and the second intermediate medium 140. For example, first intermediate medium 130 may include a medium having a relatively high refractive index (e.g. H2O). For example, second intermediate medium 140 may include an oil based medium. If the first intermediate medium 130 is H2O and the second intermediate medium 140 is oil based, an interface may be formed between the first intermediate medium 130 and the second intermediate medium.

Charges may be applied to electrode 110 of intermediate medium receptor 100 by charge supply unit 150, in accordance with embodiments. An interface between first intermediate medium 130 and second intermediate medium 140 may be controlled by the electrostatic force of the charges to obtain a desired and/or predetermined numerical aperture. For example, when the form of the interface is changes, the incident angle of light 1 may change so that a high refractive index can be obtained. In embodiments, light 1 passes through reticle 50 and intermediate medium receptor 100, and is then applied to photoresist layer 30 so that photoresist layer 30 may be patterned.

Example FIGS. 3A to 3E are sectional views of a semiconductor device illustrating processes of forming a pattern using an immersion lithography apparatus, in accordance with embodiments. As illustrated in example FIG. 3A, underlayer 23 and photoresist layer 30 may be formed on and/or over semiconductor substrate 21, in accordance with embodiments. Underlayer 23 may be formed of and/or include at least one of a SiON layer, a polycrystalline silicon layer, a nitride layer, an oxide layer, boron-phosphorous silicate glass (BPSG), and/or phosphorous silicate glass (PSG). In embodiments, a metal layer (e.g. a W layer, a WSix layer, a Co layer, a CoSix layer, a TiSix layer, and/or an Al layer) may be formed between semiconductor substrate 21 and underlayer 23.

In embodiments, photoresist layer 30 may be coated with at least one of poly hydroxyl styrene, poly acrylate, poly metha acrylate, poly norbornene, poly maleic anhydro, poly vinyl phenol, poly adaman, poly imide, and/or poly fluorine. In embodiments, one positive type photoresist and negative type photoresist may be used.

As illustrated in example FIG. 3B, intermediate medium receptor 100 may be provided on and/or over photoresist layer 30, in accordance with embodiments. Controlled charges may be applied to electrode 110 of the intermediate medium receptor 100 to set and/or cause a desired and/or predetermined numerical aperture.

As illustrated in example FIG. 3C, an immersion lithography process may radiate light 61 by immersion lithography to photoresist layer 30 through intermediate medium receptor 100 so that photoresist layer 30 is patterned. In embodiments, an immersion lithography process may be performed at one gas atmosphere of at least one of N, O2, Ar, and/or He.

As illustrated in example FIG. 3D, a process may radiate electronic beam 62 on the surface of patterned photoresist layer 30 to cure photoresist layer 30, in accordance with embodiments. In embodiments, a process that radiates electronic beam 62 may be performed at one gas atmosphere of at least one of N, O2, Ar, and He.

As illustrated in example FIG. 3E, underlayer 23 may be etched using cured photoresist layer 30 as a mask. Accordingly, underlayer 23 may be patterned. In embodiments, patterned underlayer 23 may correspond to at least one of dense lines, a spacer, a single line, and/or a contact hole pattern.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus, comprising:
a wafer stage configured to receive a wafer over the wafer stage;
a pattern forming photoresist layer formed over the wafer;
an intermediate medium receptor provided over the photoresist layer, wherein the intermediate medium receptor is configured to control refractive index over the photoresist layer; and
a reticle provided over the intermediate medium receptor.

2. The apparatus of claim 1, wherein the apparatus is an immersion lithography apparatus.

3. The apparatus of claim 1, wherein the intermediate medium receptor comprises transparent material.

4. The apparatus of claim 1, wherein the intermediate medium receptor comprises a case and an electrode.

5. The apparatus of claim 4, wherein the case comprises transparent material.

6. The apparatus of claim 5, wherein the case is substantially transparent.

7. The apparatus of claim 4, wherein the electrode comprises transparent material.

8. The apparatus of claim 7, wherein the electrode is substantially transparent.

9. The apparatus of claim 4, wherein the case and the electrode adhered to each other forming intermediate medium receiving space.

10. The apparatus of claim 9, wherein the intermediate receiving space is configured to hold a first intermediate medium and a second intermediate medium.

11. The apparatus of claim 10, wherein the first intermediate medium and a second intermediate medium having different specific gravities.

12. The apparatus of claim 10, wherein:
the first intermediate medium is H2O; and
the second intermediate medium is oil based.

13. The apparatus of claim 10, wherein an interface between the first intermediate and the second intermediate medium is configured to change based on changes of electrostatic force caused by charges applied to the electrode to change a numerical aperture.

14. A method comprising:
forming an underlayer over a semiconductor substrate;
forming a photoresist layer over the underlayer;
providing an intermediate medium receptor over the photoresist layer, wherein the intermediate medium receptor is configured to control refractive index over the photoresist layer by application of charges;
controlling the charges applied to the intermediate medium receptor to set a predetermined numerical aperture;
performing an immersion lithography process using the intermediate medium receptor to pattern the photoresist layer; and
patterning the underlayer using the patterned photoresist layer.

15. The method of claim 14, wherein the photoresist layer is coated with at least one of poly hydroxyl styrene, poly acrylate, poly metha acrylate, poly norbornene, poly maleic anhydro, poly vinyl phenol, poly adaman, poly imide, and poly fluorine.

16. The method of claim 14, wherein the immersion lithography process is performed at one gas atmosphere of at least one of N, O2, Ar, and He.

17. The method of claim 14, wherein the patterned underlayer corresponds to at least one of dense lines, a spacer, a single line, and a contact hole pattern.

18. The method of claim 14, wherein the intermediate medium receptor comprises a case and an electrode.

19. The method of claim 14, wherein the case and the electrode adhered to each other forming intermediate medium receiving space.

20. The method of claim 19, wherein the intermediate receiving space is configured to hold a first intermediate medium and a second intermediate medium.
